(19) United States
(12) Patent Application Publication
(10) Pub. No.: US 2025/0280235 A1
(43) Pub. Date: Sep. 4, 2025

(54) Correcting Group Delay in Audio Signals

(71) Applicant: Samsung Electronics Co., Ltd., Suwon-si (KR)

(72) Inventor: Sunil Ganpat Bharitkar, Stevenson Ranch, CA (US)

(21) Appl. No.: 19/069,582

(22) Filed: Mar. 4, 2025

Related U.S. Application Data
(60) Provisional application No. 63/561,065, filed on Mar. 4, 2024.

(51) Int. Cl. H04R 3/04

(52) U.S. Cl. CPC H04R 3/04

(57) ABSTRACT

In one embodiment, a method includes for each all-pass filter k in a set of one or more all-pass filters, setting an initial value of a pole amplitude rₖ and a pole frequency ωₖ. The method further includes setting minimum and maximum values of a pole-amplitude constraint and a pole-frequency constraint. Then, for each of a number of iterations q, the method includes (1) determining a group delay τₐₚ(ωₘ) of the set of all-pass filters using the pole amplitudes rₖ^{(q)} and the pole frequencies ωₖ^{(q)}; (2) determining, using an error function, a mismatch between the group delay τₐₚ(ωₘ) and a goal group delay τ_{d}(ωₘ); and (3) updating, using a stochastic-search technique and based on the mismatch, rₖ and ωₖ. The method concludes with generating a final set of all-pass filters using rₖ and ωₖ from the final iteration.

### PRIORITY CLAIM

This application claims the benefit under 35 U.S.C. § 119 of U.S. Provisional Patent Application No. 63/561,065 filed Mar. 4, 2024, which is incorporated by reference herein.

### TECHNICAL FIELD

This application generally relates to correcting group delay in audio signals.

### BACKGROUND

Signal processing on consumer devices (e.g., TVs, soundbars, etc.) is used to enhance the output audio. Such signal processing includes perceptual bass enhancement, loudspeaker-room equalization, upmixing, and spatial rendering with head-related transfer functions (HRTF), to name a few examples. Signal processing (including factoring loudspeaker-room acoustics) will introduce phase distortion (non-uniform group delay) in the signal chain, which needs to be modeled and corrected in order to yield high-quality audio.

The phase delay of a system defines the time delay of sinusoidal frequency components passing through that system. Phase delay can be frequency dependent, in that a system's phase-delay response varies as a function of frequency. Group delay is the negative derivate of phase shift with respect to frequency, and group delay is often used to determine the delay of an envelope, or packet, that defines a modulated waveform.

### BRIEF DESCRIPTION OF THE DRAWING

FIG. 1 illustrates an example method for improved determinations of the parameters of a set of all-pass filters, resulting in better approximations of the desired group delay to introduce to an audio signal.

FIG. 2 illustrates an example computing system.

### DESCRIPTION OF EXAMPLE EMBODIMENTS

Digital audio processing typically involves filtering the signal and other linear or non-linear processing. Audio processing can introduce phase or group-delay variations in the signal before that signal plays from a speaker. In addition, a speaker and the room it plays in (or headphones) also add phase nonlinearity. For example when a main or surround loudspeaker sums with a subwoofer, spectral notches are observed in the crossover region which lead to unwanted attenuation of sound. The spectral notches are a result of the phase responses of each of the loudspeaker-room responses that introduce non-coherent summation. The threshold of audibility of such group delay distortion in the pass band of human hearing can be as low as 2 ms.

Modeling and optimizing group delay functions with all-pass filters is essential in many audio applications, including (i) phase compensation to linearize phase response in the pass band of a loudspeaker (ii) representation of musical instruments for sound synthesis as well as creating audio effects, (iii) decorrelation of audio signals between channels for improved spatiality perception, (iv) feedback delay networks (FDNs) to synthesize reverberation, (v) reducing the peak amplitude of signals, and (vi) coherent summation of loudspeaker and subwoofer responses measured in a room to compensate for spectral notches in the total response.

Group delay correction can occur in series with audio processing that creates group delay. In other words, processing an audio signal can create group delay, and this group delay can be corrected, after processing (and e.g., prior to digital-to-analog conversion), by introducing a group-delay correction that essentially undoes the group delay introduced by the signal processing. This type of correction is also referred to as equalization or “main chain” group-delay correction. For instance, headphones, mobile phones, and other consumer devices that have built-in loudspeakers typically use a single processing chain, and therefore delay equalization can improve the output audio quality.

Group delay can also occur when different audio processing happens largely in parallel. For instance, “main chain” processing may be applied to an audio signal, while at the same time one or more “side chain” processing is applied to the signal. The processed main-chain and side-chain signals are then added together to form the composite audio signal. However, the main-chain processing and each side-chain processing may introduce different amounts of group delay, and therefore in order to correctly add the processed signals, a group delay must be modeled and imposed on the main chain and/or side chain processed signal. Said another way, group-delay correction here ensures that there is not a mismatch between signals that undergo parallel processing due to differences in group delay caused by the different processes, thereby ensuring that the composite audio signal actually sums together as intended. As one example, side chain processing may include perceptual bass extension (PBE), for example as described in U.S. Pat. No. 11,950,089, and this PBE description is incorporated herein by reference. The techniques of this disclosure may be used to correct group-delay mismatch between main chain audio processing and PBE processing, for example by modeling the group delay that needs to be introduced to the PBE-processed signal to match the group delay of the main chain process, thereby ensuring that the signals correctly sum together.

Because audio processing introduces group delay to an audio signal, improving the audio signal requires introducing a desired group delay τ_{d} to the audio signal that corrects the group delay introduced by the processing. In practice, however, generating an arbitrarily complex group delay is not feasible, and therefore the desired group delay τ_{d} is modeled, or approximated, using all-pass filters. As explained below, each all-pass filter in a set of all-pass filters has parameters that control the resulting group delay introduced by the set of all-pass filters, and therefore approximating the group delay τ_{d} via the set of all-pass filters requires determining the parameters of each all-pass filters such that the collective set of all-pass filters generates a phase delay that models τ_{d}.

However, determining the parameters of a set of all-pass filters that best approximate a desired group delay τ_{d} is a complex task, and determining the best possible parameters is generally not possible using current techniques. Thus, conventional state-of-the-art approaches (e.g., using an autoregressive model or a Hessian-based model) sub-optimally determine the parameters of a set of all-pass filters that best approximate τ_{d}. Said another way, current techniques for modeling all-pass filters result in parameters values that are in fact not optimal, but what the optimal parameters are or how to determine them for general τ_{d} functions is not clear.

In contrast, and as described below, the techniques of this disclosure provide superior determinations of the parameters for a set of all-pass filters, resulting in improved approximations of the desired group delay τ_{d} to introduce to an audio signal, thereby resulting in improved audio output.

The transfer function of a second-order all-pass filter with complex conjugate poles {zₖ, z*ₖ} can be expressed as:

$$\begin{matrix}{H}_{ap} ( z , {z}_{k} ) = \frac{{z}^{- 1} - {z}_{k}^{*}}{1 - {z}_{k} {z}^{- 1}} \frac{{z}^{- 1} - {z}_{k}}{1 - {z}_{k}^{*} {z}^{- 1}} \\ = \frac{{\vert {z}_{k} \vert}^{2} - 2 {z}^{- 1} ℜ ( {z}_{k} ) + {z}^{- 2}}{1 - 2 {z}^{- 1} ℜ ( {z}_{k} ) + {z}^{- 1} {\vert {z}_{k} \vert}^{2}} \\ {H}_{ap} ( z ) = {\prod }_{k = 1}^{P} {H}_{ap} ( z , {z}_{k} ) \\ {H}_{model} ( z ) = {z}^{- R} {H}_{ap} ( z )\end{matrix} \qquad ( 4 )$$

where [symbol] (⋅) denotes the real part of the complex number zᵢ=rᵢe^{jw}^{ᵢ}, and where rᵢ is the pole amplitude, ωᵢ is the pole frequency at which the pole is located, and R is a fixed delay. The phase response of a second-order all-pass filter Øₐₚ(ω), is

$${∅}_{ap} ( ω ) = - 2 ω - 2 arctan ( \frac{{r}_{i} sin ( {θ}_{i}^{-} )}{1 - {r}_{i} cos ( {θ}_{i}^{-} )} ) - 2 arctan ( \frac{{r}_{i} sin ( {θ}_{i}^{+} )}{1 - {r}_{i} cos ( {θ}_{i}^{+} )} ) \qquad ( 5 )$$

with θᵢ^{±}=ω±ωᵢ. From equation (5), the group delay τₐₚ(ω) resulting from the all-pass filters is:

$$\begin{matrix}{τ}_{ap} ( ω ) = \frac{2 ( 1 - {r}_{i} cos ( {θ}_{i}^{-} ) )}{1 - 2 {r}_{i} cos ( {θ}_{i}^{-} ) + {r}_{i}^{2}} + \frac{2 {r}_{i} cos ( {θ}_{i}^{+} ) - {r}_{i}}{1 - 2 {r}_{i} cos ( {θ}_{i}^{+} ) + {r}_{i}^{2}} \\ {τ}_{ap} ( ω ) = \frac{2 ( 1 - {r}_{i} cos ( {θ}_{i}^{-} ) )}{1 - 2 {r}_{i} cos ( {θ}_{i}^{-} ) + {r}_{i}^{2}} + \frac{2 {r}_{i} cos ( {θ}_{i}^{+} ) - {r}_{i}}{1 - 2 {r}_{i} cos ( {θ}_{i}^{+} ) + {r}_{i}^{2}}\end{matrix} \qquad ( 6 )$$

Since τ_{d}(ωᵢ) is the desired group delay to introduce to the system, at certain frequencies ω=ωᵢ the desired group delay is βᵢ=τ_{d}(ωᵢ). Adopting ω=ωᵢ as the pole frequencies and then algebraically simplifying Eq. (6), the all-pass pole amplitude rᵢ can be obtained as the roots of the following third-order polynomial:

$$( {β}_{i} + 2 ) {r}_{i}^{3} - ( 2 {β}_{i} cos ( 2 {ω}_{i} ) + 2 cos ( 2 {ω}_{i} ) + {β}_{i} ) {r}_{i}^{2} + ( {β}_{i} - 2 cos ( 2 {ω}_{i} ) + ( 2 {β}_{i} cos ( 2 {ω}_{i} ) ) {r}_{i} + ( 2 - {β}_{i} ) \qquad ( 7 )$$

The valid solution is the one that yields |rᵢ|<1.

In this disclosure, the group delay that should be obtained to introduce group-delay corrections to a system is τ_{d}(ωₘ). In a forward-modeling approach in which the goal is to match the group delay of a side chain to the group delay of a main chain, the desired group delay may be written as τ_{d}(ωₘ)=τ_{mc}(ωₘ)+R₁, where τ_{mc}(ωₘ) is the group delay introduced by the main processing chain and R₁ is a fixed delay. In this example, τ_{d}(ωₘ) would be implemented in the side chain to match its group delay with the main chain. Alternatively, the main chain could include the cascade of all-pass filters to introduce a resulting frequency-dependent group-delay that matches with the frequency-dependent delay in the side-chain incurred from any side-chain processing of the audio.

In an equalizing approach in which the goal is to undo the group delay that was introduced by a system's processing, the desired group delay may be written as τ_{d}(ωₘ)=−τ_{sys}(ωₘ)+R₂, where τ_{sys}(ωₘ) is the group delay introduced by the system and R₂ is a fixed delay. The approaches here are not mutually exclusive: for instance, one set of all-pass filters may be used in a forward-modeling approach to match the group delay between processing chains, and then an equalizing approach may be used to adjust the overall group delay of the composite signal.

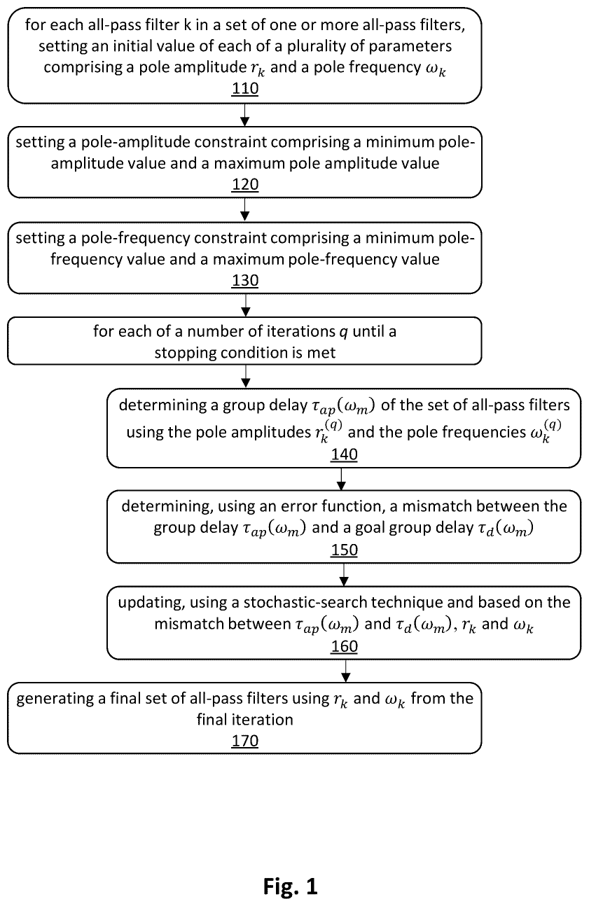

FIG. 1 illustrates an example method for improved determinations of the parameters of a set of all-pass filters, resulting in better approximations of the desired group delay to introduce to an audio signal. The example method of FIG. 1 uses stochastic search to determine the best parameters for a set of all-pass filters in order to approximate τ_{d}. For instance, one type of stochastic search is Bayesian optimization. Bayesian optimization is a global hyperparameter optimization technique that is best suited for optimization with around 20 or fewer hyperparameters. The method builds a surrogate function for the objective and quantifies the uncertainty in that surrogate using Gaussian process regression. Furthermore, several parameters are used for initialization, including the type of acquisition function that guides the sampling on optimal hyperparameters. The search parameter bounds for the pole amplitudes are set on the basis of the maximum and minimum values of the group delay to be modeled. Similarly, the limits for the pole frequencies are set to be the edge frequencies over which the pole optimization is to be achieved while minimizing an error function.

Another type of stochastic search is Simulated Annealing (SA). Simulated Annealing models the physical process of heating a material and slowly lowering the temperature to decrease defects, thus minimizing the energy of the system towards the optimal solution. At each iteration of the SA algorithm, a new set of hyperparameters is randomly generated within the limits specified as box constraints, from which the distance of the trial point form the current point is calculated with a probability distribution PR(∇Ψ̅_{SD})=1/(1+exp(∇Ψ̅_{SD}/T_{anneal,k})) with current temperature T_{anneal,k}. The algorithm accepts all new points that lower an objective function but also, with a certain probability, points that increase the energy. The annealing schedule used is typically exponential in nature T_{anneal,k}=T⁰/log(k) with T⁰ being the initial temperature at k=1.

Step 110 of the example method of FIG. 1 includes, for each all-pass filter k in a set of one or more all-pass filters, setting an initial value of each of multiple parameters that include at least a pole amplitude rₖ and a pole frequency ωₖ. In other words, step 110 includes setting the initial values rₖ, ωₖ for each all-pass filter that will be used in the system. In particular embodiments, the initial values may be set randomly (within certain constraints, as discussed above). Other embodiments may set the initial values using an existing technique for doing so, such as by using an autoregressive model or a Hessian-based model. In particular embodiments, setting the initial value may be performed by choosing the frequency values ω=ωᵢ, where ωᵢ are the frequency values at which the desired group delay is determined. Then, the initial pole amplitudes may be determined using the pole-amplitude closed-form analytic approach of equation 7. Particular embodiments may also set an initial value for the fixed delay.

Step 120 of the example method of FIG. 1 includes setting a pole-amplitude constraint that includes a minimum pole-amplitude value and a maximum pole amplitude value (e.g., {r_{k,min}, r_{k,max}}, where r_{k,min}>0, r_{k,max}<1), and step 130 includes setting a pole-frequency constraint that includes a minimum pole-frequency value and a maximum pole-frequency value (e.g., {ω_{k,min}, ω_{k,max}}). Particular embodiments may also set constraints for the fixed delay value, e.g., {Rₘᵢₙ, Rₘₐₓ}.

Then, for each of a number of iterations q until a stopping condition is met, steps 140-160 are iteratively performed. Step 140 includes determining a group delay τₐₚ(ωₘ) of the set of all-pass filters using the pole amplitudes rₖ^{(q)} and the pole frequencies ωₖ^{(q)}. In other words, the group delay τₐₚ(ωₘ) is determined using the pole amplitude values and the pole frequency values for the q-th iteration, e.g., using cascade of second-order sections of all-pass filters expressed in equation 6. The stopping condition may be one or more of a predetermined amount of time (e.g., a set number of seconds), a predetermined number of iterations, or both. This disclosure contemplates that any suitable stopping condition may be used, and in general, longer run times result in improved all-pass filter performance, but the increase in performance per unit time or iteration tends to decrease over time.

Step 150 of the example method of FIG. 1 includes determining, using an error function, a mismatch between the group delay τₐₚ(ωₘ) and a goal group delay τ_{d}(ωₘ). For instance, particular embodiments may use the root-mean-square error function set forth in equation 8, below, although this disclosure contemplates that any suitable error function may be used.

Step 160 of the example method of FIG. 1 includes updating, using a stochastic-search technique and based on the mismatch between τₐₚ(ωₘ) and τ_{d}(ωₘ), rₖ and ωₖ. For instance, Bayesian optimization or simulated annealing techniques may be used to determine the values of rₖ and ωₖ that minimize the error function (e.g., equation 8) for that iteration. After step 160, the iteration counter (i.e., q), if one is used, increments, and steps 140-160 repeat until the stopping condition is met, with each iteration using the values of rₖ and ωₖ determined in the previous iteration.

In particular embodiments, step 160 may include adjusting the values of the pole amplitudes (i.e., rₖ) while keeping the ωₖ at their the initial values (e.g., when the initial values are ω=ωᵢ, where ωᵢ are the frequency values at which the desired group delay is determined).

Once the stopping condition is met, then step 170 of the example method of FIG. 1 includes generating a final set of all-pass filters using the pole amplitudes rₖ and the pole frequencies ωₖ from the final iteration. This set of all-pass filters can then be used to improve signal degradation due to group delay, e.g., as in the forward processing and equalization techniques described above.

Algorithm 1, below, shows an example implementation of the method of FIG. 1, using the following error function:

$$σ = 10 {log}_{10} ( \frac{1}{N} {\sum }_{m = 1}^{N} W ( m ) {‖ {τ}_{d} ( {ω}_{m} ) - {τ}_{model} ( {ω}_{m} ) ‖}_{2}^{2} ) \\ {τ}_{model} ( {ω}_{m} ) = {\sum }_{k = 1}^{P} {τ}_{ap}^{( k )} ( {ω}_{m} ) \qquad ( 8 )$$

where τₐₚ^{(k)}(ωₘ) is the group delay that corresponds to the k-th second order all-pass filter in equation (6), and W(m) is a weighting function (which may be set to unity if no specific weighting is desired). The constraint |rₖ|<1, ∀k is ensured during optimization using search techniques. While equation 8 illustrates an example of forward modeling (i.e., per the “model” subscript in τ_{model}), the same error function may likewise be used for equalization techniques.

Algorithm 1: All-pass pole-optimization using stochastic search
(e.g., Bayesian optimization or Simulated Annealing)

Result: Result: (rₖ*, ωₖ*, delay R*), k = 1, ... , P

| | | minimum: σ |
|---|---|---|
| 1 | Initialize: Set the initial values of the poles (rₖ^{(q)}, ωₖ^{(q)}) and fixed delay R^{(q)} (where q=0 is | |
| | | the iteration) randomly or in a prescribed fashion (e.g., (7) or from the optimized poles |
| | | of [35], [34]) depending on the problem. Desired group delay to model τ_{d}(ω). |
| 2 | Set pole amplitude constraints {r_{k,min}, r_{k,max}} (where r_{k,min} > 0, r_{k,max} < 1), pole angles | |
| | | {ω_{k,min}, ω_{k,max}}, and fixed delay limits {Rₘᵢₙ, Rₘₐₓ} |
| 3 | Set number of iterations (or maximum amount of time T) for termination; | |
| 4 | while t ≤ T seconds ∨ q ≤ Q iterations do | |
| 5 | \| | Compute τₐₚ(ωₘ) with (rₖ^{(q)}, ωₖ^{(q)}) using (6); |
| 6 | \| | Compute σ using (8); |
| 7 | \| | Update (rₖ^{(q)}, ωₖ^{(q)}) and using R^{q} using bayesopt or simulannealbnd to minimize (8); |
| 8 | \| | q = q + 1 |

| | |
|---|---|
| 9 | end |

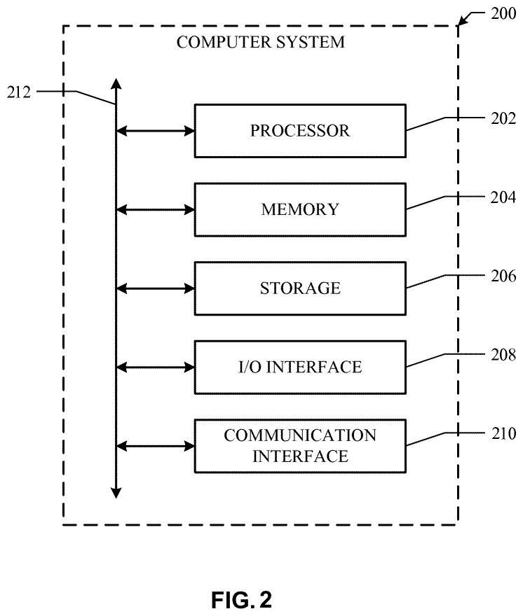

FIG. 2 illustrates an example computer system 200. In particular embodiments, one or more computer systems 200 perform one or more steps of one or more methods described or illustrated herein. In particular embodiments, one or more computer systems 200 provide functionality described or illustrated herein. In particular embodiments, software running on one or more computer systems 200 performs one or more steps of one or more methods described or illustrated herein or provides functionality described or illustrated herein. Particular embodiments include one or more portions of one or more computer systems 200. Herein, reference to a computer system may encompass a computing device, and vice versa, where appropriate. Moreover, reference to a computer system may encompass one or more computer systems, where appropriate.

This disclosure contemplates any suitable number of computer systems 200. This disclosure contemplates computer system 200 taking any suitable physical form. As example and not by way of limitation, computer system 200 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, or a combination of two or more of these. Where appropriate, computer system 200 may include one or more computer systems 200; be unitary or distributed; span multiple locations; span multiple machines; span multiple data centers; or reside in a cloud, which may include one or more cloud components in one or more networks. Where appropriate, one or more computer systems 200 may perform without substantial spatial or temporal limitation one or more steps of one or more methods described or illustrated herein. As an example and not by way of limitation, one or more computer systems 200 may perform in real time or in batch mode one or more steps of one or more methods described or illustrated herein. One or more computer systems 200 may perform at different times or at different locations one or more steps of one or more methods described or illustrated herein, where appropriate.

In particular embodiments, computer system 200 includes a processor 202, memory 204, storage 206, an input/output (I/O) interface 208, a communication interface 210, and a bus 212. Although this disclosure describes and illustrates a particular computer system having a particular number of particular components in a particular arrangement, this disclosure contemplates any suitable computer system having any suitable number of any suitable components in any suitable arrangement.

In particular embodiments, processor 202 includes hardware for executing instructions, such as those making up a computer program. As an example and not by way of limitation, to execute instructions, processor 202 may retrieve (or fetch) the instructions from an internal register, an internal cache, memory 204, or storage 206; decode and execute them; and then write one or more results to an internal register, an internal cache, memory 204, or storage 206. In particular embodiments, processor 202 may include one or more internal caches for data, instructions, or addresses. This disclosure contemplates processor 202 including any suitable number of any suitable internal caches, where appropriate. As an example and not by way of limitation, processor 202 may include one or more instruction caches, one or more data caches, and one or more translation lookaside buffers (TLBs). Instructions in the instruction caches may be copies of instructions in memory 204 or storage 206, and the instruction caches may speed up retrieval of those instructions by processor 202. Data in the data caches may be copies of data in memory 204 or storage 206 for instructions executing at processor 202 to operate on; the results of previous instructions executed at processor 202 for access by subsequent instructions executing at processor 202 or for writing to memory 204 or storage 206; or other suitable data. The data caches may speed up read or write operations by processor 202. The TLBs may speed up virtual-address translation for processor 202. In particular embodiments, processor 202 may include one or more internal registers for data, instructions, or addresses. This disclosure contemplates processor 202 including any suitable number of any suitable internal registers, where appropriate. Where appropriate, processor 202 may include one or more arithmetic logic units (ALUs); be a multi-core processor; or include one or more processors 202. Although this disclosure describes and illustrates a particular processor, this disclosure contemplates any suitable processor.

In particular embodiments, memory 204 includes main memory for storing instructions for processor 202 to execute or data for processor 202 to operate on. As an example and not by way of limitation, computer system 200 may load instructions from storage 206 or another source (such as, for example, another computer system 200) to memory 204. Processor 202 may then load the instructions from memory 204 to an internal register or internal cache. To execute the instructions, processor 202 may retrieve the instructions from the internal register or internal cache and decode them. During or after execution of the instructions, processor 202 may write one or more results (which may be intermediate or final results) to the internal register or internal cache. Processor 202 may then write one or more of those results to memory 204. In particular embodiments, processor 202 executes only instructions in one or more internal registers or internal caches or in memory 204 (as opposed to storage 206 or elsewhere) and operates only on data in one or more internal registers or internal caches or in memory 204 (as opposed to storage 206 or elsewhere). One or more memory buses (which may each include an address bus and a data bus) may couple processor 202 to memory 204. Bus 212 may include one or more memory buses, as described below. In particular embodiments, one or more memory management units (MMUs) reside between processor 202 and memory 204 and facilitate accesses to memory 204 requested by processor 202. In particular embodiments, memory 204 includes random access memory (RAM). This RAM may be volatile memory, where appropriate Where appropriate, this RAM may be dynamic RAM (DRAM) or static RAM (SRAM). Moreover, where appropriate, this RAM may be single-ported or multi-ported RAM. This disclosure contemplates any suitable RAM. Memory 204 may include one or more memories 204, where appropriate. Although this disclosure describes and illustrates particular memory, this disclosure contemplates any suitable memory.

In particular embodiments, storage 206 includes mass storage for data or instructions. As an example and not by way of limitation, storage 206 may include a hard disk drive (HDD), a floppy disk drive, flash memory, an optical disc, a magneto-optical disc, magnetic tape, or a Universal Serial Bus (USB) drive or a combination of two or more of these. Storage 206 may include removable or non-removable (or fixed) media, where appropriate. Storage 206 may be internal or external to computer system 200, where appropriate. In particular embodiments, storage 206 is non-volatile, solid-state memory. In particular embodiments, storage 206 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 206 taking any suitable physical form. Storage 206 may include one or more storage control units facilitating communication between processor 202 and storage 206, where appropriate. Where appropriate, storage 206 may include one or more storages 206. Although this disclosure describes and illustrates particular storage, this disclosure contemplates any suitable storage.

In particular embodiments, I/O interface 208 includes hardware, software, or both, providing one or more interfaces for communication between computer system 200 and one or more I/O devices. Computer system 200 may include one or more of these I/O devices, where appropriate. One or more of these I/O devices may enable communication between a person and computer system 200. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 208 for them. Where appropriate, I/O interface 208 may include one or more device or software drivers enabling processor 202 to drive one or more of these I/O devices. I/O interface 208 may include one or more I/O interfaces 208, where appropriate. Although this disclosure describes and illustrates a particular I/O interface, this disclosure contemplates any suitable I/O interface.

In particular embodiments, communication interface 210 includes hardware, software, or both providing one or more interfaces for communication (such as, for example, packet-based communication) between computer system 200 and one or more other computer systems 200 or one or more networks. As an example and not by way of limitation, communication interface 210 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 210 for it. As an example and not by way of limitation, computer system 200 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 200 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. Computer system 200 may include any suitable communication interface 210 for any of these networks, where appropriate. Communication interface 210 may include one or more communication interfaces 210, where appropriate. Although this disclosure describes and illustrates a particular communication interface, this disclosure contemplates any suitable communication interface.

In particular embodiments, bus 212 includes hardware, software, or both coupling components of computer system 200 to each other. As an example and not by way of limitation, bus 212 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 212 may include one or more buses 212, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

This disclosure contemplates a system that includes one or more non-transitory computer readable storage media storing instructions; and one or more processors coupled to the one or more non-transitory computer readable storage media and operable to execute the instructions to perform certain functions includes embodiments in which those functions are performed by a single processor, embodiments in which those functions are performed by multiple processors that each perform all the functions, and embodiments in which those functions are performed by multiple processors (e.g., in separate computing devices) where each processor performs at least one function but less than all recited functions.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend.

What is claimed is:

1. A method comprising:
for each all-pass filter k in a set of one or more all-pass filters, setting an initial value of each of a plurality of parameters comprising a pole amplitude rₖ and a pole frequency ωₖ;
setting a pole-amplitude constraint comprising a minimum pole-amplitude value and a maximum pole amplitude value;
setting a pole-frequency constraint comprising a minimum pole-frequency value and a maximum pole-frequency value;
for each of a plurality of iterations q until a stopping condition is met:
determining a group delay τₐₚ(ωₘ) of the set of all-pass filters using the pole, amplitudes rₖ^{(q)} and the pole frequencies ωₖ^{(q)};
determining, using an error function, a mismatch between the group delay τₐₚ(ωₘ) and a goal group delay τ_{d}(ωₘ); and
updating, using a stochastic-search technique and based on the mismatch between τₐₚ(ωₘ) and τ_{d}(ωₘ), rₖ and ωₖ; and
generating a final set of all-pass filters using rₖ and ωₖ from the final iteration.

2. The method of claim 1, wherein the stochastic-search technique comprises Bayesian optimization.

3. The method of claim 1, wherein the stochastic-search technique comprises simulated annealing.

4. The method of claim 1, wherein the stopping condition comprises one or more of (1) a predetermined period of time or (2) a predetermined number of iterations.

5. The method of claim 1, wherein each initial value is randomly determined.

6. The method of claim 1, wherein each initial value is determined using a pole-amplitude closed-form analytic approach.

7. The method of claim 1, further comprising using the final set of all-pass filters to equalize a group delay present in an audio signal.

8. The method of claim 1, further comprising using the final set of all-pass filters for forward modeling of a group delay in an audio signal.

9. The method of claim 8, wherein the group delay comprises a main-chain group delay introduced to a perceptual bass extension side chain.

10. One or more non-transitory computer readable storage media storing instructions that are operable when executed to:
for each all-pass filter k in a set of one or more all-pass filters, set an initial value of each of a plurality of parameters comprising a pole amplitude rₖ and a pole frequency ωₖ;
set a pole-amplitude constraint comprising a minimum pole-amplitude value and a maximum pole amplitude value;
set a pole-frequency constraint comprising a minimum pole-frequency value and a maximum pole-frequency value;
for each of a plurality of iterations q until a stopping condition is met:
determine a group delay τₐₚ(ωₘ) of the set of all-pass filters using the pole amplitudes rₖ^{(q)} and the pole frequencies ωₖ^{(q)};
determine, using an error function, a mismatch between the group delay τₐₚ(ωₘ) and a goal group delay τ_{d}(ωₘ); and
update, using a stochastic-search technique and based on the mismatch between τₐₚ(ωₘ) and τ_{d}(ωₘ), rₖ and ωₖ; and
generate a final set of all-pass filters using rₖ and ωₖ from the final iteration.

11. The media of claim 10, wherein each initial value is determined using a pole-amplitude closed-form analytic approach.

12. A system comprising: one or more non-transitory computer readable storage media storing instructions; and one or more processors coupled to the one or more non-transitory computer readable storage media and operable to execute the instructions to:
for each all-pass filter k in a set of one or more all-pass filters, set an initial value of each of a plurality of parameters comprising a pole amplitude rₖ and a pole frequency ωₖ;
set a pole-amplitude constraint comprising a minimum pole-amplitude value and a maximum pole amplitude value;
set a pole-frequency constraint comprising a minimum pole-frequency value and a maximum pole-frequency value;
for each of a plurality of iterations q until a stopping condition is met:
determine a group delay τₐₚ(ωₘ) of the set of all-pass filters using the pole amplitudes rₖ^{(q)} and the pole frequencies ωₖ^{(q)};
determine, using an error function, a mismatch between the group delay τₐₚ(ωₘ) and a goal group delay τ_{d}(ωₘ); and
update, using a stochastic-search technique and based on the mismatch between τₐₚ(ωₘ) and τ_{d}(ωₘ), rₖ and ωₖ; and
generate a final set of all-pass filters using rₖ and ωₖ from the final iteration.

13. The system of claim 12, wherein the stochastic-search technique comprises Bayesian optimization.

14. The system of claim 12, wherein the stochastic-search technique comprises simulated annealing.

15. The system of claim 12, wherein the stopping condition comprises one or more of (1) a predetermined period of time or (2) a predetermined number of iterations.

16. The system of claim 12, wherein each initial value is randomly determined.

17. The system of claim 12, wherein each initial value is determined using a pole-amplitude closed-form analytic approach.

18. The system of claim 12, further comprising one or more processors coupled to the storage media and operable to execute the instructions to use the final set of all-pass filters to equalize a group delay present in an audio signal.

19. The system of claim 12, further comprising one or more processors coupled to the storage media and operable to execute the instructions to use the final set of all-pass filters for forward modeling of a group delay in an audio signal.

20. The system of claim 19, wherein the group delay comprises a main-chain group delay introduced to a perceptual bass extension side chain.
